(19) United States
(12) Patent Application Publication
(10) Pub. No.: US 2019/0280139 A1
(43) Pub. Date: Sep. 12, 2019

(54) SOLAR-POWERED ILLUMINATED DISPLAY

(71) Applicant: OptoGlo, Inc., Leominster, MA (US)

(72) Inventor: Kevin Donahue, Harvard, MA (US)

(73) Assignee: OptoGlo, Inc., Leominster, MA (US)

(21) Appl. No.: 16/294,481

(22) Filed: Mar. 6, 2019

Related U.S. Application Data
(60) Provisional application No. 62/639,722, filed on Mar. 7, 2018.

(51) Int. Cl. H01L 31/054; G02B 6/35; F21V 8/00; H02J 7/35; G09G 3/22

(52) U.S. Cl. CPC H01L 31/054; G02B 6/3522; G09G 3/22; H02J 7/355; G02B 6/0025; G02B 6/0031

(57) ABSTRACT

This disclosure describes devices that can integrate a solar energy collection device, such as a solar collection film or panel, and an illuminated display. Embodiments of the present solution include a display that includes a solar film layer topped by a transparent or semi-transparent display layer enabled by an edge-illuminated light guide. The semi-transparent display can allow sufficient light transmission to cause the solar layer to charge an integrated battery, which, in turn, can illuminates the display. This solution can enable wireless displays that can be seen day or night.

### RELATED APPLICATIONS

This application claims priority to U.S. Provisional Patent App. No. 62/639,722, filed on Mar. 7, 2018 and entitled “SOLAR DISPLAY AND SOLAR ILLUMINATION,” which is incorporated by reference herein in its entirety.

### FIELD OF DISCLOSURE

Systems and methods are described for an illuminated display composed of an image layer, an illumination layer, and a solar power layer n that can be deployed in signage, decoration, general illumination, or any other form of graphics art illumination.

### BACKGROUND

Illuminated graphic art can be composed of an image layer and an electric-powered illumination layer. In some instances, such illuminated graphic art may require access to an external power source, for example via an electrical cord.

### SUMMARY

This disclosure describes a device that is composed of an image layer, an illumination layer, and a solar-power layer containing a solar collection film or panel. The device can also include a battery for storing collected power. The current invention is facilitated by the convergence of high-efficiency LED illumination and solar collection films panels. One aspect of this invention relates to highly light transparent image and illumination layers that can appear to be opaque. This characteristic can enable the presentation of seemingly opaque graphics, such as photographs, that are also sufficiently transparent to enable sunlight to pass through and be collected by the underlying solar film, or solar panel layer, enabling sufficient battery charging to provide sufficient power to illuminate the display. For example, a four-inch wide square display including an image layer composed of an inkjet-printed image on polyester backed by a diffusion film, an illumination layer composed of an acrylic backlight illuminated by edge-mounted LEDs, and a solar layer composed of a solar film connected to a battery (e.g., a 60 mAh LIPOH battery), can have the appearance of a photograph during daytime hours, but can be backlit in the evening. In some implementations, such a display can be backlit for approximately six hours or longer, under normal daylight conditions. This disclosure provides a low-cost means of producing cordless and “green” (e.g., energy efficient and environmentally sustainable) illuminated graphics for use in a variety of applications, including advertising, decoration, and all types of signage.

As described briefly above, the present disclosure describes the integration of a solar energy collection device, such as a solar collection film or panel, and an illuminated display that may be composed of a substantially transparent image layer and illumination layers. Embodiments of the present disclosure may include a display composed of a solar film layer topped by a transparent or semi-transparent illumination layer enabled by an edge-illuminated light guide. In some implementations, the illumination layer can allow sufficient light transmission to cause the solar layer to charge an integrated battery, which, in turn, can provide power for illuminating the display. In some implementations, the image layer can be a semi-transparent overlay, such as an ink-jet printed polyester film of an image pattern that is directly embossed into one or more illumination layers. Overall, this solution can enable wireless displays that can be seen day or night.

In some implementations, the integration of the aforementioned light guide and a solar panel, or a solar film, can be used to produce a display that integrates solar power collection and the illumination of a pattern. For example, the pattern can be a printed, embossed, or molded pattern. In some implementations, the pattern to be illuminated can be composed of a light-diffusing material. As a result, a relatively low surface area can produce a coherent illuminated image. For example, an embossed halftone pattern, directly imprinted upon the illumination layer, may cover only a portion of the illumination layer (e.g., less than 10%, less than 20%, less than 30%, less than 40%, or less than 50% of the surface area of the illumination layer) can produce a fully-illuminated display while still enabling a majority of the sunlight hitting the surface of the display to reach the underlying solar collection surface. For example, in some implementations more than 60%, more than 70%, more than 80%, or more than 90% of the sunlight that is instant on the surface of the display may reach the underlying solar collection surface.

Similarly, an image layer composed of an image, such as a photograph, which may be printed or laid upon a seemingly opaque (e.g., white) transparent film, may enable fifty percent or more of the incident sunlight transmission to the underlying solar layer. In some implementations, such an arrangement can enable several hours of display illumination at night. In addition, in some implementations the systems and methods of this disclosure can use low-profile, low-power light-emitting diodes (LEDs). For example, in some implementations a display can incorporate LEDs having a thickness of about 0.5 mm, which may generate 3,000 mcd of light (e.g., at a 120-degree angle), thereby providing a backlight for a one-foot square display with 60 milliamps of power. In some implementations, such a display can be serviced by a 5 W solar film and a companion battery. By further reducing the LED thickness and efficiency of solar films, the present disclosure can also provide for the production of a solar display film that can be deployed as a printable substrate for use in a digital offset, or inkjet printer, such as an HP Indigo printer, enabling the instant production of custom illuminated solar-powered signage or other displays. Further, this disclosure provides a backlight in which a solar film can power a uniformly illuminated display that may backlight a transparent image.

At least one aspect of this disclosure is directed to a device. The device can include an illumination layer including an edge-injected light guide. The device can include a solar energy collection layer including one of a solar panel or a solar film. The device can include an image layer including at least one of a colorized transparent diffusion film or a pattern imprinted on the illumination layer.

In some implementations, the device can include one of a panel or a film. In some implementations, the device can include a layer of optical cladding configured to bind the solar collection layer to a light guide of the illumination layer. The solar collection layer can be separated from the light guide of the illumination layer by the layer of optical cladding. The layer of optical cladding can maintain total internal reflection of light within the light guide layer. In some implementations, the device can include a power storage layer including a film comprising a lithium polymer battery.

In some implementations, the at least one of the colorized transparent diffusion film or the pattern imprinted on the illumination layer can include a light-diffusing material. In some implementations, the light-diffusing material can include at least one of a white ink, a phosphorescent material, or a fluorescent material. In some implementations, the light diffusing material can be the white ink, and the white ink can be selected to be translucent to allow light collection by the solar layer.

In some implementations, the at least one of the colorized transparent diffusion film or the pattern imprinted on the illumination layer can be capped by one of a colored dye or a pigment to produce a color image.

In some implementations, the light-diffusing material can be at least one of a phosphorescent material or a fluorescent material. The device can further include a light source configured to inject light into the illumination layer to stimulate the light diffusing material. In some implementations, the light source can be configured to inject ultraviolet light into the illumination layer.

In some implementations, the at least one of the colorized transparent diffusion film or the pattern imprinted on the illumination layer can be rendered on the illumination layer by digital offset printing. In some implementations, the device can include at least one of an anti-reflection coating or an anti-reflection film selected to allow light collection by the solar energy collection layer. In some implementations, the illumination layer can be positioned on a rear side of the solar energy collection layer to provide interior illumination. In some implementations, total internal reflection within the edge-injected light guide can be frustrated by at least one or a molded pattern or an embossed pattern.

At least another aspect of this disclosure is directed to a method. The method can include fabricating an illumination layer of a display device. The illumination layer can include an edge-injected light guide. The method can include forming an image layer on the illumination layer. The image layer can include at least one of a colorized transparent diffusion film or a pattern imprinted on the illumination layer. The method can include coupling the illumination layer to a first surface of a layer of optical cladding. The method can include adhering a second surface of the layer of optical cladding, opposite the first surface, to a solar energy collection layer including one of a solar panel or a solar film.

In some implementations, forming the at least one of the colorized transparent diffusion film or the pattern imprinted on the illumination layer can include depositing a light-diffusing material on the illumination layer. In some implementations, depositing the light-diffusing material can include depositing at least one of a white ink, a phosphorescent material, or a fluorescent material.

In some implementations, the method can include capping the at least one of the colorized transparent diffusion film or the pattern imprinted on the illumination layer with one of a colored dye or a pigment to produce a color image.

In some implementations, the image layer can include a printed transparent film and an underlying diffusion film. In some implementations, the image layer can be printed using an ink selected based on a predetermined threshold level of optical efficiency for the collection of solar power by the solar energy collection layer.

### BRIEF DESCRIPTION OF DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 shows a side view of an example display device, according to an illustrative implementation.

FIG. 2 shows a side view of an example display device, according to an illustrative implementation.

FIG. 3 shows a flow chart of an example method for manufacturing a device, according to an illustrative implementation.

The details of various embodiments of the methods and systems are set forth in the accompanying drawings and the description below.

### DESCRIPTION

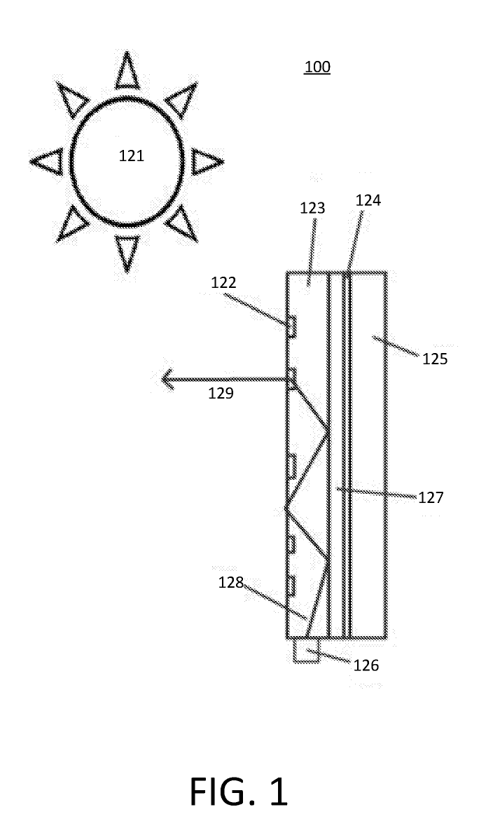

FIG. 1 shows a side view of an example display device 100, according to an illustrative implementation. The device 100 can include a light guide display layer 123 and a solar collection layer 125. The solar collection layer 125 can include a solar energy collection surface 124. Sunlight 121 (or light emitted by another light source) can pass through the light guide display layer 123 and can contact the solar energy collection surface 124 of the solar collection layer 125. Edge-injected light rays 128 from an edge-mounted light source 126 can enter the light guide 123. In some implementations, the edge-mounted light source can be one or more LEDs. The light rays 128 can be frustrated by light-diffusing markings 122, which may also be referred to as imprints 122, thereby causing emission of light 129 from the surface of the display device 100 in the areas where the light-diffusing markings 122 are present. In some implementations, the device 100 can include a layer of optical cladding 127 positioned between the light guide display layer 123 and the solar collection layer 125. The layer of optical cladding 127 can be configured to maintain the total internal reflection of light within the light guide layer. In some implementations, the display device 100 can be used to backlight a transparent film or to present an image composed of the markings 122 illuminated by frustrated total internal reflection.

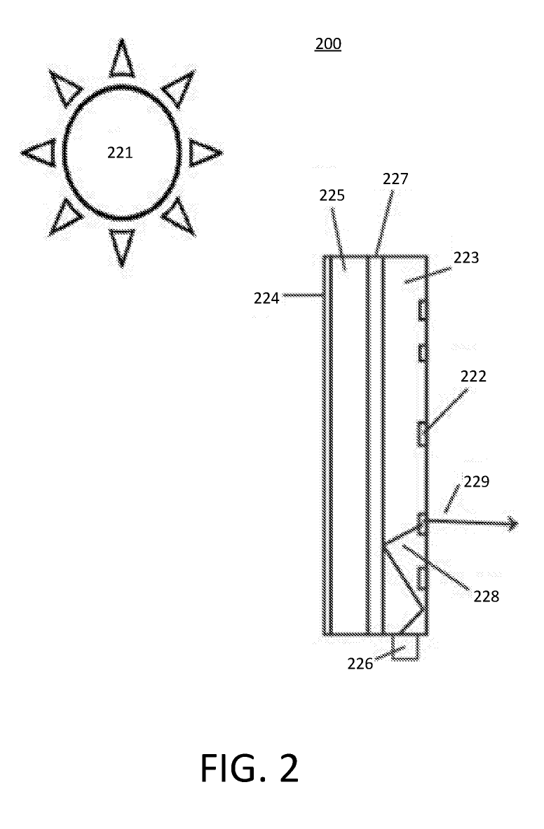

FIG. 2 shows a side view of an example display device 200, according to an illustrative implementation. The display device 200 can include many of the features shown and described in connection with the display device 100 of FIG. 1, and like reference numerals refer to like elements. For example, the display device 200 can include a light guide display layer 223 and a solar collection layer 225. The solar collection layer 225 can include a solar energy collection surface 224. Sunlight 221 (or light emitted by another light source) can contact the solar energy collection surface 224 of the solar collection layer 225. Edge-injected light rays 228 from an edge-mounted light source 226 can enter the light guide 223. In some implementations, the edge-mounted light source 226 can be one or more LEDs. The light rays 228 can be frustrated by light-diffusing markings 122, which may also be referred to as imprints 222, thereby causing emission of light 229 from the surface of the display device 200 in the areas where the light-diffusing markings 222 are present. In some implementations, the device 200 can include a layer of optical cladding 227 positioned between the light guide display layer 223 and the solar collection layer 225. The layer of optical cladding 227 can be configured to maintain the total internal reflection of light within the light guide layer. The display device 200 can differ from the display device 100 of FIG. 1 in that the light guide layer 223 can be adhered to a rear side of the solar collection layer 225 in the display device 200, rather than the front side as shown in FIG. 1. Thus the arrangement of the light guide layer 223 and the solar collection layer 225 can provide interior illumination in the display device 200.

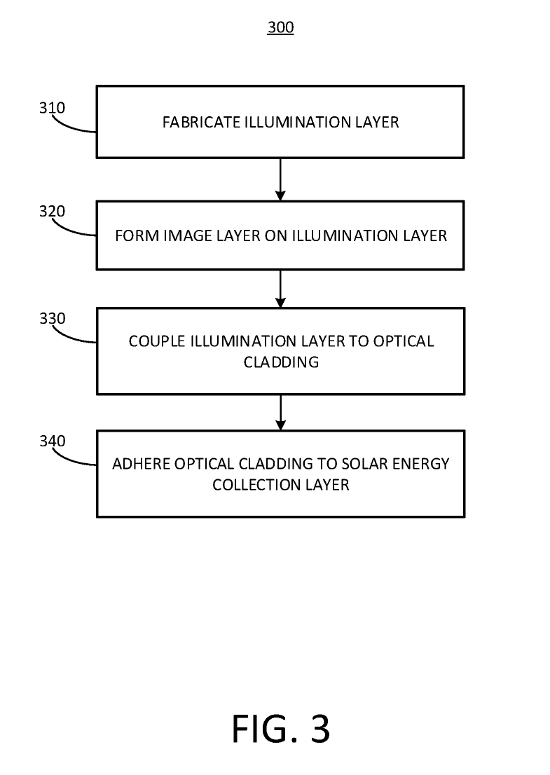

FIG. 3 shows a flow chart of an example method 300 for manufacturing a device, according to an illustrative implementation. The method 300 can include fabricating an illumination layer (step 310). In some implementations, the illumination layer can include an edge-injected light guide. The method can include forming an image layer on the illumination layer (step 320). In some implementations, the image layer can include at least one of a colorized transparent diffusion film or a pattern imprinted on the illumination layer. In some implementations, forming the at least one of the colorized transparent diffusion film or the pattern imprinted on the illumination layer can include depositing a light-diffusing material on the illumination layer. For example, depositing the light-diffusing material can include depositing at least one of a white ink, a phosphorescent material, or a fluorescent material. In some implementations, the image layer can include a printed transparent film and an underlying diffusion film. In some implementations, the image layer can be printed using an ink selected based on a predetermined threshold level of optical efficiency for the collection of solar power by the solar energy collection layer

The method 300 can include coupling the illumination layer to a layer of optical cladding (step 330). In some implementations, the illumination layer can be coupled to a first surface of the layer of optical cladding. The method can include adhering the layer of optical cladding to a solar energy collection layer (step 340). In some implementations, the solar energy collection layer can include at least one of a solar panel or a solar film. The solar energy collection layer can be adhered to a second surface of the optical cladding, opposite the first surface of the layer of optical cladding. In some implementations, the method can also include capping the at least one of the colorized transparent diffusion film or the pattern imprinted on the illumination layer with one of a colored dye or a pigment to produce a color image.

In some implementations, multiple devices can be fabricated according to the method 300. In some implementations, multiple such devices may be interconnected together. For example, several relatively small devices can be formed. The devices can be physically arranged in an array, such as a square or rectangular array including one or more devices in each row and column. Thus, each device can form a portion of a surface of the array. In some implementations, the devices can be configured to operate together so that the array of devices forms a single display. For example, the image pattern formed on the illumination layer of each device can be selected based on the position of the device within the larger array.

In some implementations, the image pattern for each device can be selected to be a portion of a larger image pattern having a surface area corresponding to a surface area of the larger array. Thus, each device can display a unique pattern that, together with the images formed by the other devices in the array, forms a larger image at the scale of the entire array.

This disclosure describes solar powered illuminated displays or backlighting devices that may include a light guide layer for displaying an illuminated pattern, which can be deployed to illuminate an image overlay such as a printed film, or to present an illuminated image pattern. In some implementations, the illuminated image overlay or illuminated image pattern can be achieved via the frustration of the total internal reflection of edge-injected light in light guide layer. In some implementations, an underlying solar energy collection layer can be used to collect the energy required to power the illumination layer. For example, the solar energy collection layer can be a solar panel or solar film. In some embodiments of the present solution, the solar collection layer and light guide layer can be separated and bound together by a layer of optical cladding that maintains the total internal reflection of the light within the light guide layer.

In some implementations, a device may integrate or may include a power storage layer, such as a film composed of a lithium polymer battery. In some embodiments, the image pattern can be formed from a light-diffusing material, such as a white ink or a phosphorescent or fluorescent material. In some implementations, such ink may be translucent to increase light collection by the underlying solar layer. Further, in some embodiments, the image layer may be composed of a printed-transparent film and an underlying diffusion film that may appear to be white, but may also exhibit substantial light transmission, such as the 80-degree diffusion films produced by Fusion Optix of Woburn, Massachusetts and Luminit of Pasadena Calif., which can feature greater than 80% light transmission.

In some implementations, the image layer can make use of one or more printed inks selected to avoid or substantially reduce colorization that may limit solar collection efficiency due to light filtration. For example, the ink can be selected based on a predetermined threshold level of optical efficiency or a predetermined range of optical efficiencies to allow light to pass through and be collected by the underlying solar collection layer. In some implementations, optical efficiency can be measured as a percentage of light that is permitted to pass through the ink. For example, an ink may be selected to improve, and in some cases to maximize, optical efficiency with respect to other inks that have lower optical efficiency (e.g., may allow a smaller fraction of light to pass through). In some implementations, the ink may be selected to be transparent for a particular wavelength or range of wavelengths of light, based on the characteristics of the solar collection layer. For example, the ink may be selected to have a relatively high degree of transparency or optical efficiency with respect to one or more wavelengths of light that can be collected by the solar collection layer, even if the ink has a relatively low degree of transparency or optical efficiency with respect to other wavelengths of light.

In some implementations, the image layer can be rendered by digital offset printing, or by another printing method. In some implementations, the display can be capped with an anti-reflection coating or an anti-reflection film that may help to improve or increase light collection in the solar collection layer of the device. In some implementations, the order in which layers are stacked in the device can be reversed or modified. For example, in some implementations the light guide can be adhered to a rear side, rather than a front side, of the solar collection layer to provide interior illumination.

In some implementations, the total internal reflection of light in the light guide layer can be frustrated by a molded or embossed pattern. In some implementations, the light-diffusing pattern can be capped by a colored dye or a pigment to produce a colored image, which may be a full-color image. In some implementations, the light injected into the light guide can be ultraviolet light. As a result, the light may be capable of stimulating the illumination of a halftone pattern composed of photochromic, fluorescent, or phosphorescent materials. In some implementations, multiple illumination layers that each produce illumination by the frustration of total internal reflection of multiple colored-light sources can be deployed to produce a multi-color image. For example, such multiple illumination layers may be arranged in a stacked configuration in the device.

It should be noted that certain passages of this disclosure may reference terms such as “first” and “second” in connection with devices, mode of operation, transmit chains, antennas, etc., for purposes of identifying or differentiating one from another or from others. These terms are not intended to merely relate entities (e.g., a first device and a second device) temporally or according to a sequence, although in some cases, these entities may include such a relationship. Nor do these terms limit the number of possible entities (e.g., devices) that may operate within a system or environment.

While the foregoing written description of the methods and systems enables one of ordinary skill to make and use what is considered presently to be the best mode thereof, those of ordinary skill will understand and appreciate the existence of variations, combinations, and equivalents of the specific embodiment, method, and examples herein. The present methods and systems should therefore not be limited by the above described embodiments, methods, and examples, but by all embodiments and methods within the scope and spirit of the disclosure.

What is claimed:

1. A device comprising:
an illumination layer comprising an edge-injected light guide;
a solar energy collection layer comprising one of a solar panel or a solar film; and
an image layer comprising at least one of a colorized transparent diffusion film or a pattern imprinted on the illumination layer.

2. The device of claim 1, wherein the device comprises one of a panel or a film.

3. The device of claim 1, further comprising a layer of optical cladding configured to bind the solar collection layer to a light guide of the illumination layer, wherein the solar collection layer is separated from the light guide of the illumination layer by the layer of optical cladding, and wherein the layer of optical cladding maintains total internal reflection of light within the light guide layer.

4. The device of claim 1, further comprising a power storage layer including a film comprising a lithium polymer battery.

5. The device of claim 1, wherein the at least one of the colorized transparent diffusion film or the pattern imprinted on the illumination layer comprises a light-diffusing material.

6. The device of claim 5, wherein the light-diffusing material comprises at least one of a white ink, a phosphorescent material, or a fluorescent material.

7. The device of claim 6, wherein the light diffusing material comprises the white ink, and wherein the white ink is selected to be translucent to allow light collection by the solar layer.

8. The device of claim 1, wherein the at least one of the colorized transparent diffusion film or the pattern imprinted on the illumination layer is capped by one of a colored dye or a pigment to produce a color image.

9. The device of claim 1, wherein the light-diffusing material comprises at least one of a phosphorescent material or a fluorescent material, the device further comprising a light source configured to inject light into the illumination layer to stimulate the light diffusing material.

10. The device of claim 9, wherein the light source is configured to inject ultraviolet light into the illumination layer.

11. The device of claim 1, wherein the at least one of the colorized transparent diffusion film or the pattern imprinted on the illumination layer is rendered on the illumination layer by digital offset printing.

12. The device of claim 1, further comprising at least one of an anti-reflection coating or an anti-reflection film selected to allow light collection by the solar energy collection layer.

13. The device of claim 1, wherein the illumination layer is positioned on a rear side of the solar energy collection layer to provide interior illumination.

14. The device of claim 1, wherein total internal reflection within the edge-injected light guide is frustrated by at least one or a molded pattern or an embossed pattern.

15. The device of claim 1, wherein the image layer comprises a printed transparent film and an underlying diffusion film.

16. The device of claim 15, wherein the image layer is printed using an ink selected based on a predetermined threshold level of optical efficiency for the collection of solar power by the solar energy collection layer.

17. A method comprising:
fabricating an illumination layer of a display device, the illumination layer comprising an edge-injected light guide;
forming an image layer on the illumination layer, the image layer comprising at least one of a colorized transparent diffusion film or a pattern imprinted on the illumination layer;
coupling the illumination layer to a first surface of a layer of optical cladding; and
adhering a second surface of the layer of optical cladding, opposite the first surface, to a solar energy collection layer comprising one of a solar panel or a solar film.

18. The method of claim 17, wherein forming the at least one of the colorized transparent diffusion film or the pattern imprinted on the illumination layer comprises depositing a light-diffusing material on the illumination layer.

19. The method of claim 18, wherein depositing the light-diffusing material comprises depositing at least one of a white ink, a phosphorescent material, or a fluorescent material.

20. The method of claim 17, further comprising capping the at least one of the colorized transparent diffusion film or the pattern imprinted on the illumination layer with one of a colored dye or a pigment to produce a color image.
